(19) United States
(12) Patent Application Publication
(10) Pub. No.: US 2005/0265404 A1
(43) Pub. Date: Dec. 1, 2005

(54) Luminance enhancement apparatus and method

(76) Inventor: Ian Ashdown, West Vancouver (CA)

Correspondence Address: DORSEY & WHITNEY, LLP;INTELLECTUAL PROPERTY DEPARTMENT, 370 SEVENTEENTH STREET, SUITE 4700, DENVER, CO, 80202-5647, US

(21) Appl. No.: 11/140,654

(22) Filed: May 27, 2005

Related U.S. Application Data
(60) Provisional application No. 60/574,950, filed on May 28, 2004.

(51) Int. Cl. H01S 3/10

(52) U.S. Cl. 372/20

(57) ABSTRACT

The present invention provides a luminance enhancement apparatus and method for use with light-emitting elements comprising a conversion system adjacent the light-emitting element for converting electromagnetic radiation of one or more wavelengths to alternate wavelengths. This conversion process can be enabled by the absorption of the one or more wavelengths by the conversion system and emission of the alternate wavelengths thereby. The conversion system comprises a predetermined surface relief pattern on the face opposite the light-emitting element to provide a means for reducing absorption of the emitted alternate wavelengths in addition to providing a means for reflection of the emitted alternate wavelengths from the conversion system with a reduced number of reflections, thereby enhancing the illumination provided by the light-emitting element. As the present invention operates on principles of increased surface area and self-excitation of the conversion materials through the use of a predetermined surface relief pattern, the present invention may be applied to both organic LEDs, phosphor-coated semiconductor LEDs, and light-emitting elements coated with a population of quantum dots embedded in a host matrix.

### CROSS-REFERENCE TO RELATED APPLICATION

This application claims the benefit under 35 U.S.C. § 119(e) of U.S. Provisional Application No. 60/574,950, filed May 28, 2004, and entitled “Luminance Enhancement Apparatus and Method”, which is hereby incorporated by reference herein in its entirety.

### FIELD OF THE INVENTION

The present invention field of illumination and in particular to apparatus and methods of enhancing the luminance from light-emitting elements.

### BACKGROUND

There are a number of light-emitting elements with these including semiconductor light-emitting devices, organic light-emitting devices and others as would be readily understood. For example, organic light-emitting devices (OLEDs) comprise thin layers of organic materials deposited on a substrate that when excited by the flow of electrical current, emit visible light. Such devices can be useful in applications such as displays for cellular telephones, personal digital assistants, flat-screen television displays and advertising signage. As the technology behind OLEDs matures, they are also expected to provide cost-effective general illumination for commercial and residential spaces. Semiconductor light-emitting devices (LEDs) similarly comprise thin layers of semiconductor materials such as AlInGaP or InGaN deposited onto a substrate and are useful in many of the same applications as OLEDs.

Another example of a point light source comprises a population of quantum dots embedded in a host matrix, and a primary light source which causes the dots to emit secondary light of a specific colour(s). In this example the size and distribution of the quantum dots are chosen to allow a light of a particular colour to be emitted therefrom. This type of illumination device is disclosed in U.S. Pat. No. 6,501,091 and U.S. Patent Application No. 20030127659.

Having particular regard to a typical OLED, this device comprises a cathode layer, a transparent anode layer, and an organic light-emitting layer disposed between the cathode and the anode on a suitable substrate. In addition, a phosphorescent layer may be disposed on the device in order to absorb light emitted by the organic light-emitting layer and re-emit light of different wavelengths, thereby providing a means for producing polychromatic or “white” light.

As an example, an organic light-emitting layer may emit light within the blue region of the visible spectrum. Upon being transmitted through a transparent anode, some of this blue light, or excitation light, may be absorbed by a phosphorescent material and re-emitted, or converted, within the yellow region of the visible spectrum. The resulting combination of this blue and yellow light can be perceived as white light by an observer. More generally, both organic light-emitting polymers and phosphorescent conversion materials associated therewith may be chosen to provide polychromatic light with a wide range of relative spectral power distributions, for example.

The phosphorescent material used for this type of application is typically an inorganic phosphor powder wherein the particles are suspended in a transparent matrix. The density of the suspended material is carefully chosen such that the desired portion of blue light emitted by the organic light-emitting material is absorbed by the phosphor particles and converted to yellow light, having regard to the above example. However, this process may not be completely efficient in that some of the blue light may be absorbed and converted into thermal energy. In addition, the phosphor particles may reabsorb emitted yellow light and similarly convert this into thermal energy as well. A further problem may occur when the phosphor particles become “saturated”, wherein for example a further increase in excitation light does not produce a corresponding increase in converted light. All of these effects tend to decrease the efficiency of an OLED, where the efficiency is defined as the ratio of optical output power, which is measured in lumens, to the electrical input power which is measured in watts.

U.S. Patent Application No. 2003/0111955 and Duggal et al., 2002, “Organic Light-Emitting Devices for Illumination Quality White Light,” Applied Physics Letters 80(19):3470-0.3472, both describe a white light OLED that illustrates these issues. FIG. 1 illustrates an OLED that comprises an indium tin oxide (ITO) anode 16 that is deposited on a glass substrate 18. A 60-nm thick hole transport film 14 of poly(3,4)-ethylenedioxythiophene/polystyrene sulfonate (PEDOT/PSS) is spin coated onto the anode 16, followed by a 70-nm thick, spin-coated film 12 of polyfluorene-based blue light-emitting polymer (LEP) manufactured by Cambridge Display Technologies (Cambridge, UK). A 4-nm thick cathode 10 of NaF is then thermally evaporated onto the LEP. The conversion materials for this OLED comprise three layers that are bonded to the glass substrate 18 using a 25-micron thick optical laminating tape. In the first two layers 20 and 22, perylene orange and perylene red organic dyes are respectively dispersed into thin films of polymethlymethacrylate (PMMA). The third and final layer 24 comprises cerium-activated Y(Gd)AG phosphor granules dispersed in poly-dimethyl siloxane (PDMS) silicone.

As noted by Duggal et al., the quantum yields of the organic dyes in the PMMA host was determined to be greater than 0.98, while the quantum yield of the Y(Gd)AG:Ce phosphor was measured as 0.86, wherein the quantum yield is defined as the ratio of the number of photons emitted over the number of photons absorbed. Duggal et al. modeled each phosphorescent layer n as absorbing a fraction of the incident photons and re-emitting them at different wavelengths, according to:
Sₙ(λ)=Sₙ₋₁(λ)exp[−αₙ(λ)δₙ]+WₙCₙ(λ)Pₙ(λ) (1)
where the first and second terms describe the absorption and emission, respectively, by the n^{th} phosphorescent layer. Here, Sₙ(λ) is the output spectrum, αₙ(λ) is the absorption coefficient, and δₙ is the mean optical path length through the layer. It would be readily understood that the mean optical path length is greater than the layer thickness due to scattering and non-perpendicular propagation through the layer.

The phosphor emission coefficient Pₙ(λ) is normalized such that its integral over all visible wavelengths is equal to unity. The phosphor emission coefficient is multiplied by the weight factor Wₙ, which is given by:

$${W}_{n} = {Q}_{n} {\int }_{λ}^{} {S}_{n - 1} ( λ ) \{ 1 - exp [ - {α}_{n} ( λ ) {δ}_{n} ] \} ⅆ λ \qquad ( 2 )$$

where Qₙ is the quantum yield of the phosphorescent material in layer n. Finally, the self-absorption correction factor Cₙ(λ) is given by:

$${C}_{n} ( λ ) = \frac{exp [ - {α}_{n} ( λ ) {δ}_{n} ]}{1 - {Q}_{n} {\int }_{λ}^{} {P}_{n} ( λ ) \{ 1 - exp [ - {α}_{n} ( λ ) {δ}_{n} ] ⅆ λ \}} \qquad ( 3 )$$

Duggal et al. reported good correlation between this model and their laboratory measurements, wherein Sₙ(λ), Pₙ(λ) and Qₙ were experimentally determined and δₙ for each phosphorescent layer was a free parameter. It was further noted that by varying the value δₙ of the different conversion layers, the correlated color temperature (CCT) of the white light could be varied between 3000 and 6000 Kelvin, which represent “warm white” and “cool white”, respectively.

As can be seen from Equation 1 however, the magnitude of Sₙ(λ) is exponentially dependent on the absorption coefficient αₙ(λ) in both terms, which is itself dependent on the density of the organic dyes and inorganic phosphor powders in the PMMA and PDMS hosts. Therefore the ratio of converted light to the incident light is limited by the maximum possible density of the phosphorescent materials. In addition, by increasing the thickness of a layer the mean optical path length increases, thereby resulting in increased absorption for both the incident and re-emitted light.

Duggal et al. also noted that their model could be used to estimate the ratio of white light to blue light power efficiency according to the following:

$$\frac{{P}_{white}}{{P}_{blue}} = \frac{{\int }_{λ}^{} ( {S}_{n} ( λ ) / λ ) ⅆ λ}{{\int }_{λ}^{} ( {S}_{0} ( λ ) / λ ) ⅆ λ} \qquad ( 4 )$$

where S₀(λ) is the output spectrum of a blue light LED, which in accordance with the finite quantum yields of the conversion layers and the fact that the higher-energy incident photons are converted into lower-energy photons, as defined by Stokes losses, this ratio should always be less than unity. What was observed by Duggal et al. however was a ratio considerably in excess of unity. Duggal et al. noted that the escape angle for photons internally emitted by the OLED is dependent on the refractive index of the active medium, for example the LEP 12 as illustrated in FIG. 1, and the refractive index of the adjacent transparent media, which in this case in the PEDOT/PSS layer 14, the ITO layer 16 and the glass substrate 18. Together, the refractive index of the active medium and the adjacent transparent material define an “escape cone” of angles 28 through which the emitted photons can exit the OLED structure 26, as illustrate in FIG. 2. Photons that have an incident angle upon the adjacent transparent media outside of this “escape cone” are typically reflected back into the LEP material 12 due to total internal reflection of the transparent media. As taught in \check{Z}ukauskas et al., 2002, Introduction to Solid-State Lighting, New York, N.Y.: Wiley-Interscience, and others, the “escape cone” angle 28 illustrated in FIG. 2 can be defined by:
θ_{c}=arcsin(nₑ/nₛ) (5)
where nₛ is the refractive index of the exposed surface of the OLED and nₑ is the refractive index of the surrounding medium. Having regard to FIG. 1 the exposed surface is the Y(Gd)AG:Ce layer 24 and the surrounding medium is typically air which has a refractive index of 1.00.

Referencing surface roughening of light-emitting diode die surfaces as defined for example in U.S. Pat. No. 3,739,217 and Schnitzer et al., 1993, “30% External Quantum Efficiency from Surface Textured, Thin-Film Light-Emitting Diodes,” Applied Physics Letters 63(16):2174-2176), Duggal et al. postulated that the scattering of photons within the translucent Y(Gd)AG:Ce layer 24, effectively widened the escape cone thereby increasing the measured external quantum efficiency of the OLED. This hypothesis was confirmed by applying a tape with non-absorbing scattering particles to the top surface of the OLED in place of the conversion layer; the device incorporating this scattering tape exhibited a 27 percent increase in light output compared to the same device without the scattering tape. Surface roughening techniques may therefore be used for obtaining moderate increases in OLED efficiency. As an example, Schubert, E. F., 2003, Light-Emitting Diodes, Cambridge, UK: Cambridge University Press, taught that the ratio of light escaping a light-emitting diode, P_{escape},to the ratio of light generated within the device, P_{source} is given by:

$$\frac{{P}_{escape}}{{P}_{source}} = \frac{1}{2} ( 1 - cos {θ}_{c} ) \approx \frac{1}{4 {n}_{s}^{2}} \qquad ( 6 )$$

where θ_{c} is the escape angle and ns is the refractive index of the uppermost OLED layer, wherein this refractive index is typically in the region of 1.5. Surface roughening is known to reduce the effective refractive index at the substrate-air interface, which can account for a wider escape cone angle and a resulting increased power efficiency. The minimum effective refractive index attainable by surface roughening, however, is typically 1.25 and this value can represent a maximum attainable power efficiency increase of 45 percent.

Having regard to light-emitting devices that are semiconductor LEDs, a typical embodiment of a white light LED is shown in FIG. 3, wherein an n-doped gallium nitride (GaN) layer 34 is deposited on a sapphire substrate 32. A p-doped GaN layer 36 is then deposited on layer 34, followed by a transparent ITO layer 38 that functions as a current spreader. A metallic reflector layer 30 is then deposited on the opposite side of the sapphire layer 32, and wire bonds 40 are soldered to the device to provide an electrical path, wherein these components include the LED “die.” When current flows across the junction between the GaN layers 34 and 36, the “die” emits visible light that is mostly within the blue region of the spectrum for this form of device.

In order to produce white light, a layer of inorganic phosphorescent particles 42, which may be cerium-activated YAG, is applied in a slurry to the exposed surface of the LED die, as disclosed by Mueller-Mach, et al., 2002, “High-Power Phosphor-Converted Light-Emitting Diodes Based on III-Nitrides,” IEEE Journal on Selected Topics in Quantum Electronics 8(2):339-345, for example. The inorganic phosphorescent particles absorb a portion of the excitation light and convert this light into yellow light. The resultant combination of blue and yellow light is thereupon perceived as white light by an observer. In all respects, the problems identified with conversion phosphorescent materials for OLEDs similarly apply to phosphor-coated semiconductor LEDs, which are typically referred to as pcLEDs.

In addition, there are point light sources that comprises a population of quantum dots embedded in a host matrix, and a primary light source, wherein the primary light source may be for example, an LED, a solid-state laser, or a microfabricated UV source. The dots desirably are composed of an undoped semiconductor such as CdSe, and may optionally be overcoated to increase photoluminescence. The light emitted by the point light source may be emitted solely from the dots or from a combination of the dots and the primary light source. As previously described for both the OLED and the LED wherein there were problems relating to the conversion of phosphorescent materials, these can similarly apply to this type of device.

A further method of increasing the power efficiency currently available is the use of “brightness enhancement” films which comprise a grooved surface as disclosed in U.S. Pat. No. 5,161,041 and commercially available as 3M Vikuiti Brightness Enhancement Films, 3M Corporation, St. Paul, Minn. These films however, only increase the luminance or “photometric brightness” of a planar light source in a direction substantially normal to the light source surface without changing the amount of emitted light or “luminous exitance”, where “luminance” and luminous exitance” are as defined in ANSI/IESNA, 1996, Nomenclature and Definitions for Illuminating Engineering, ANSI/IESNA RP-16-96, New York, N.Y.: Illuminating Engineering Society of North America. As a result, these films increase the luminance or “photometric brightness” of the underlying light source in a direction substantially normal to the film, however they typically decrease the luminance at off-axis viewing angles.

U.S. Pat. No. 5,502,626 discloses a “high efficiency fluorescent lamp device,” with a grooved surface or a grooved trapezoidal surface that increases the efficiency of converted light. For operation this device however, requires a serpentine mercury arc lamp emitting ultraviolet light to excite a phosphor coating deposited on a glass or polymer substrate whose trapezoidal structures face towards the excitation source. U.S. Pat. No. 5,502,626 further teaches that the sole purpose of the “V-groove” pattern is to maximize the surface area presented to the incident ultraviolet light, and that accordingly the optimum angle between adjacent V-grooves is 90 degrees. However, an optimal angle for a phosphor or other conversion layer that may be self-excited by its emitted light, is not considered in this patent. In addition, this patent does not consider the advantages of an area light source in physical contact with the substrate without an intervening air gap therebetween.

European Patent Application No. 0514346A2, discloses trapezoidal grooved structures with a “refractive film of a high degree of luminescence.” This film however, relies on an external light source, and the structures provide a retroreflection of the incident light. As such, the groove angle is constrained to 90 degrees and the optimal angle for a phosphor or other conversion material that may be self-excited by its emitted light is not considered. In addition, the preferred phosphorescent material is copper-activated ZnS or a similar material whose peak emission is in the green portion of the spectrum to coincide with the peak spectral responsivity of the human eye. The film is further intended for use in road signs and hazard markets, wherein the phosphorescent material is excited by the ultraviolet radiation present in direct sunlight and emits green light during the night when the excitation source has been removed.

There is therefore a need for an apparatus and method that can provide greater efficiency increases than those obtainable by surface roughening alone for OLEDs, as well as for phosphor coated LEDs and quantum dot light-emitting diodes.

This background information is provided for the purpose of making known information believed by the applicant to be of possible relevance to the present invention. No admission is necessarily intended, nor should be construed, that any of the preceding information constitutes prior art against the present invention.

### SUMMARY OF THE INVENTION

An object of the present invention is to provide a luminance enhancement means and method. In accordance with an aspect of the present invention, there is provided an illumination apparatus comprising: one or more light-emitting elements that serve as a primary source of electromagnetic radiation; and a conversion system positioned to interact with the electromagnetic radiation produced by the one or more light-emitting elements, said conversion system having a predetermined surface relief pattern on a face opposite the one or more light-emitting elements, said conversion system further including a conversion means for changing one or more wavelengths of the electromagnetic radiation from the one or more light-emitting elements to electromagnetic radiation having one or more alternate wavelengths; wherein said one or more light-emitting elements are adapted for connection to a power source for activation thereof.

In accordance with another aspect of the present invention, there is provided a method for enhancing luminance produced by one or more point light sources, said method comprising the steps of: providing the one or more point light sources, each comprising a light-emitting element that serves as a primary source of electromagnetic radiation and includes a conversion system for changing one or more wavelengths of the electromagnetic radiation to one or more alternate wavelengths of electromagnetic radiation; and forming a predetermined surface relief pattern on a face of the conversion system, said face being opposite the light-emitting element.

### BRIEF DESCRIPTION OF THE FIGURES

FIG. 1 shows an example of an OLED with a composite conversion layer, shown in cross-section according to the prior art.

FIG. 2 shows the escape cone for light emitted from the surface of a light-emitting device into free air according to the prior art.

FIG. 3 shows an example of a semiconductor LED with a conversion layer, shown in cross-section according to the prior art.

FIG. 4 shows a cross-section of one embodiment of the present invention as applied to an OLED with a composite conversion layer.

FIG. 5 shows a cross-section of one embodiment of the present invention as applied to a semiconductor LED with a conversion layer.

FIG. 6 shows an embodiment of the present invention applied to a light-emitting element comprising a population of quantum dots embedded in a host matrix and a primary light source.

FIG. 7 shows an embodiment of the present invention associated with a remote light-emitting element.

FIG. 8 shows the emission and partial re-absorption of light from a section of a predetermined surface relief pattern according to one embodiment of the present invention.

FIG. 9 shows a perspective view of a surface design of the conversion system according to one embodiment of the present invention.

FIG. 10 shows a perspective view of another surface design of the conversion system according to one embodiment of the present invention.

FIG. 11 shows a top view of a computer simulation representing the enhancement of the illumination produced by a collection of light-emitting elements using a conversion system having a surface design according to FIG. 9.

FIG. 12 shows a top view of a computer simulation representing the enhancement of the illumination produced by a collection of light-emitting elements using a conversion system having a surface design according to FIG. 10.

FIG. 13 shows a perspective view of a computer simulation representing the enhancement of the illumination produced by a collection of light-emitting elements using a conversion system having a surface design according to FIG. 9.

FIG. 14 shows a perspective view of a computer simulation representing the enhancement of the illumination produced by a collection of light-emitting elements using a conversion system having a surface design according to FIG. 10.

### DETAILED DESCRIPTION OF THE INVENTION

Definitions

The term “light-emitting element” is used to define any device that emits radiation in the visible region, or any other region of the electromagnetic spectrum, when a potential difference is applied across it or a current is passed through it, for example, a semiconductor or organic light-emitting diode, quantum dot light-emitting diode, polymer light emitting diode or other similar devices as would be readily understood.

Unless defined otherwise, all technical and scientific terms used herein have the same meaning as commonly understood by one of ordinary skill in the art to which this invention belongs.

The present invention provides a luminance enhancement apparatus and method for use with light-emitting elements comprising a conversion system adjacent to the light-emitting element for converting electromagnetic radiation of one or more wavelengths to alternate wavelengths. This conversion process can be enabled by the absorption of radiation with the one or more wavelengths by the conversion system and emission of radiation with the alternate wavelengths thereby. The conversion system comprises a predetermined surface relief pattern on the face opposite the light-emitting element to provide a means for reducing absorption of the emitted alternate wavelengths in addition to providing a means for reflection of the emitted alternate wavelengths from the conversion system with a reduced number of reflections, thereby enhancing the illumination provided by the light-emitting element. As the present invention operates on principles of increased surface area and self-excitation of the conversion materials through the use of a predetermined surface relief pattern, the present invention may be applied to both organic LEDs, phosphor-coated semiconductor LEDs, and light-emitting elements coated with a population of quantum dots embedded in a host matrix.

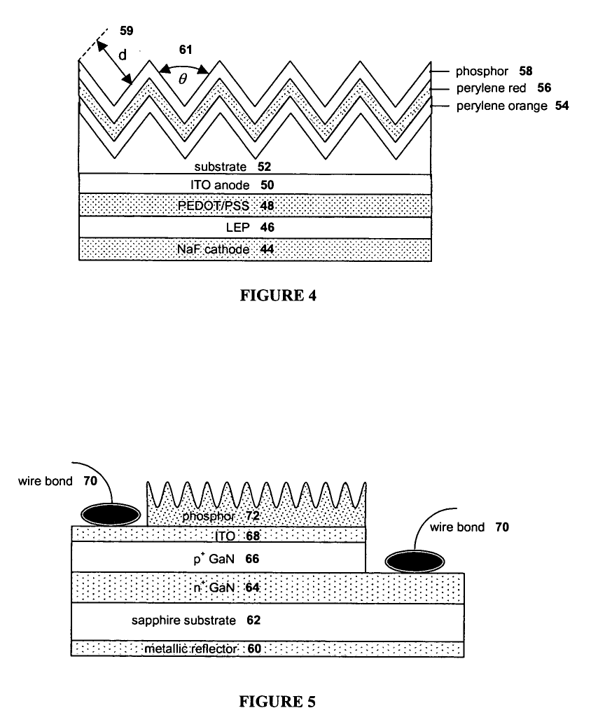

Having regard to organic light-emitting diodes (OLED), FIG. 4 illustrates one embodiment of the present invention adapted for association with an OLED structure. FIG. 4 shows a white light OLED structure having a transparent glass or plastic substrate 52 that comprises a predetermined surface relief pattern in the form of a plurality of “V” on the top surface when viewed in cross section. This relief pattern comprises a substantially triangular cross-section with an angle θ 61 between the intersecting planes, wherein this relief pattern can be molded or embossed onto one side of the substrate 52. As an example and as illustrated in FIG. 4, a white light OLED as described by Duggal et al. can be formed by depositing multi-layers of material on the side of the substrate opposite to the relief pattern. These layers can comprise an ITO (indium tin oxide) anode layer 50, a PEDOT/PSS (poly(3,4)-ethylenedioxythiophene/polystyrene sulfonate) hole transport layer 48, a blue LEP (light-emitting polymer) layer 46, and a NaF (sodium fluoride) layer 44. On the relief pattern side of the substrate a number of additional layers can be deposited, wherein these layers for the conversion means. In this example, these layers comprise a perylene orange organic dye layer 54, a perylene red organic dye layer 56, and a Y(Gd)AG:Ce (cerium and gallium-doped yttrium aluminum oxide garnet) phosphor layer 58. As will be appreciated by those skilled in the art of organic light-emitting devices, alternate OLED constructions can equally be associated with the present invention for example including those disclosed in U.S. Pat. No. 5,874,803, wherein the light emitting elements comprise a plurality of light emitting layers in a stacked arrangement and a downward conversion phosphor layer.

Furthermore, layers 54-58 as illustrated in FIG. 4 can be manufactured using a variety of known techniques, including dip coating, web coating, and ink jet printing thereby forming the layers providing the conversion means for changing the wavelengths of the electromagnetic radiation produced by the OLED. In being deposited on the predetermined relief pattern of the substrate, the effective surface area of the conversion means layers 54-58 is increased with respect to that of prior art planar layers. This fact is advantageous in that the incident excitation light generated by the light-emitting polymer layer 46 directly irradiates a greater quantity of phosphorescent material without being absorbed by the bulk of this material. For example, using the same density of phosphorescent materials in layers 54-58 per unit area of OLED structure, the conversion means layers can therefore be made thinner, which can reduce the absorption of excitation light and the self-absorption of emitted light within these conversion means layers thereby enhancing the luminous exitance.

It should be noted that having further regard to FIG. 4, the predetermined relief pattern with respect to the layer thicknesses are not illustrated to scale. The dimension d 59 of the predetermined surface relief pattern may vary from micrometers to centimetres, wherein this size can be determined based on manufacturing techniques and application requirements, for example. The principle of operation of the present invention as disclosed herein is scale-invariant.

In an alternate embodiment, the OLED structure can be contiguous or segmented, as determined by manufacturing techniques and application requirements. For example, the OLED device may be manufactured on a planar substrate and then cut into segments that are assembled providing the predetermined surface relief pattern, for example a plurality of “V” grooves.

FIG. 5 illustrates an embodiment of the present invention associated with a semiconductor light-emitting diode (LED). In this embodiment, the conversion system comprises the predetermined surface relief pattern created within the phosphor coating associated with the LED. In this example, the LED comprises a n-doped gallium nitride (GaN) layer 64 deposited on a sapphire substrate 62. A p-doped GaN layer 66 is then deposited on layer 64, followed by a transparent ITO anode layer 68. A metallic reflector layer 60 is then deposited on the opposite side of the sapphire layer 62 and wire bonds 70 are soldered to the device. A slurry of inorganic phosphorescent particles can applied to the exposed surface of the LED die to form the conversion means layer 72 and a predetermined surface relief pattern is created on the exposed surface of the conversion means layer. Similar to substrate 52 illustrated in FIG. 4, the predetermined surface relief pattern can be created by molding, embossing, or stamping.

With respect to Equations 1 and 3 and with reference to FIG. 5, it is evident that the absorption of the incident and re-emitted light by the conversion means layer 72 can be minimized by minimizing the mean optical path length 6 through the layer. This can be achieved by limiting the directions of the light emitted by the LED to those approximately perpendicular to the plane of conversion means layer 72. As shown by Equation 5, this can be achieved by ensuring that the escape cone angle determined by the quotient of the indices of refraction of the ITO anode layer 68 and the conversion means layer 72 is minimized. This can be accomplished by choosing an optically transparent matrix material with a high index of refraction for the conversion means layer 72, such as thermosetting polymers as manufactured by Nikko Denko Corporation of Ibaraki, Japan.

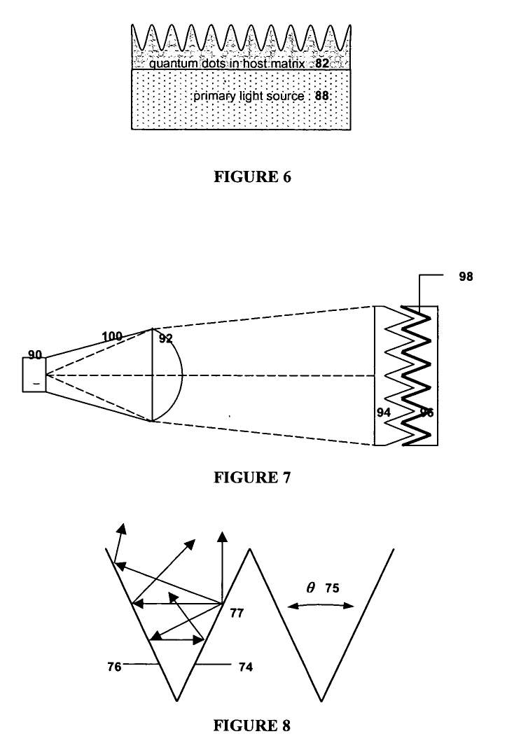

FIG. 6 illustrates the present invention associated with a light-emitting element comprising a population of quantum dots embedded in a host matrix and a primary light-emitting source. Similar to the phosphor-coated LED in FIG. 5, the exposed surface of the quantum dot matrix 82, which forms the conversion means, can be molded, embossed or stamped with a predetermined surface relief pattern, thereby forming the conversion system. The primary light source 88 associated with this form of light-emitting element may be, for example, an LED, a solid-state laser, or a microfabricated UV source. Also similar to the phosphor-coated LED in FIG. 5, the quantum dot matrix is preferably an optically transparent material with a high index of refraction.

FIG. 7 illustrates an embodiment of the present invention associated with a remote light-emitting element 90 such as, for example, an LED, a solid-state laser, or a microfabricated UV source wherein an optical element 92 collects and collimates the emitted light to preferentially irradiate a conversion means layer 96 bonded to a transparent substrate 98 in a direction substantially perpendicular to the plane of said conversion means layer, and where said optical element 92 may be, for example, a convex lens, a Fresnel lens, a diffractive lens, or a holographic optical element. A brightness enhancement film 94 can be interposed between conversion means layer 96 and optical element 92 such that the incident radiation is internally reflected and refracted in directions substantially perpendicular to the plane of each face of conversion means layer 96. In one embodiment, an index-matching fluid or gel 100 is interposed between the light-emitting element 90 and optical element 92 to improve the collection of emitted light.

Having regard to a cross sectional view of one embodiment of the predetermined surface relief pattern of the conversion system, FIG. 8 shows a number of rays of light exiting face 74 at location 77 of the exposed surface of the conversion system, including both unabsorbed excitation light and converted light. Depending on the exit angle with respect to the surface normal, a ray may escape from the conversion system or intersect the opposite face 76. If a ray of converted light intersects face 76, it has a probability of being reflected or absorbed, as determined by the spectral reflectance of the intersected material. Assuming a reflectance value of, for example 80 percent, most of the converted light will typically exit the conversion system having a predetermined surface relief pattern after one or two reflections as illustrated in FIG. 8. The angle θ 75 between the intersecting planes forming faces 74 and 76 can vary between 0 and 180 degrees, and more particularly between 20 and 90 degrees. The range of angles between the intersecting faces can also be provided in alternate orientations of the cross sectional view, for example when the predetermined surface relief pattern comprises a plurality of pyramid structures.

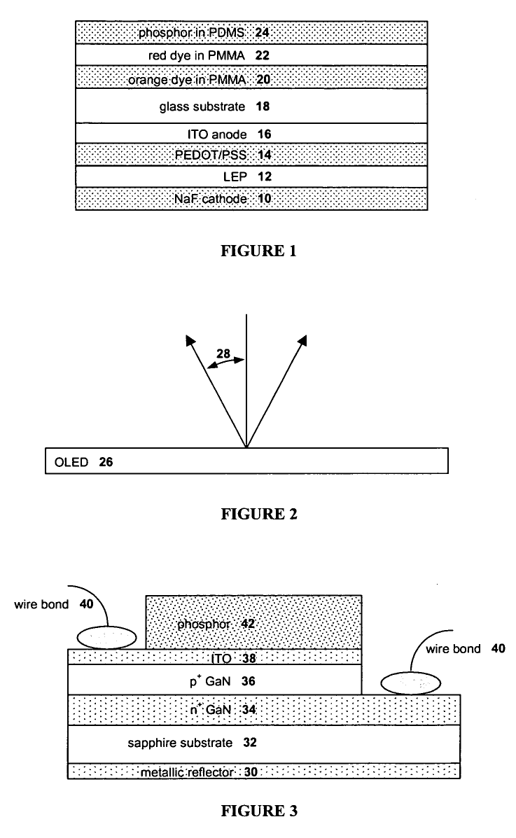

If a ray of excitation light, from the light-emitting element, intersects face 76, it has a probability of being absorbed by conversion system, specifically the conversion means, and being converted. Having regard to a conversion system associated with an OLED, for example as illustrated in FIG. 4, as the conversion means layers deposited on the substrate are made thinner, they can become more transparent in comparison to prior art OLED structures as illustrated in FIG. 1, and hence can have an improved efficiency. Additionally the phosphor layer associated with a semiconductor can additionally be made thinner due to the increase in exposed surface area provided by the predetermined surface relief pattern of the conversion system, while providing a sufficient amount of wavelength conversion needed to achieve a desired relative spectral power distribution, thereby also improving efficiency.

In a further embodiment of the present invention, faces 74 and 76 as illustrated in FIG. 8 can be surface roughened as discussed by, for example Duggal et al., to increase the escape cone angle and thereby increase the external quantum efficiency of the OLED or pcLED.

With further regard to FIG. 8, if a ray of converted light intersects face 76 and is absorbed by the conversion system, it has a probability of being re-emitted if its wavelength is within the excitation spectrum of the conversion means associated with the conversion system. In this manner the efficiency of the OLED structure can thereby be further improved. As noted by Duggal et al., the excitation and emission spectra of perlyene red, perlyene orange, and Y(Gd)AG:Ce exhibit considerable overlap, thereby enabling the above efficiency improvement. A similar overlap in the excitation and emission spectra is also true for the YAG:Ce and similar phosphorescent materials typically used for white light LEDs, wherein these forms of pcLED phosphors are defined in for example, in Mueller-Mach, R., G. O. Mueller. M. R. Krames, and T. Trottier, 2002, “High-Power Phosphor-Converted Light-Emitting Diodes Based on III-Nitrides,” IEEE Journal on Selected Topics in Quantum Electronics 8(2):339-345.

The predetermined surface relief pattern forming a portion of the conversion system can be configured in a plurality of different predetermined patterns for example, a plurality of “V” shaped or trapezoidal shaped grooves in a first direction, a plurality of conical shaped depressions or a plurality of pyramid shaped depressions wherein the polygon bases of the pyramids have an even number of sides, for example hexagon, octagon, square, rectangular and the like. In one embodiment, the surface relief pattern can be parabolic in nature, wherein for example, the “V” shaped grooves may be more similar to “U” shaped grooves and likewise for the planar sides of the pyramid shapes can have parabolic curves. A worker skilled in the art would readily understand other configurations of the predetermined surface relief pattern which can provide the desired increase in surface area of the exit surface and the desired reflective capability of the surface.

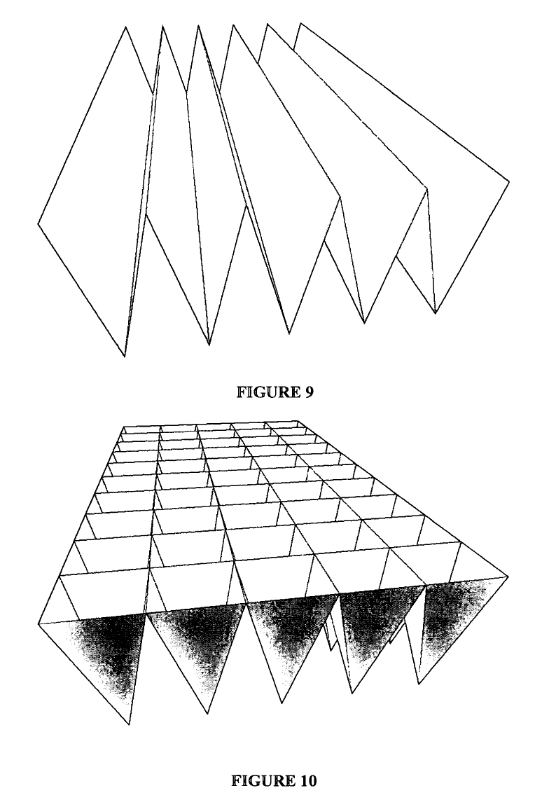

FIG. 9 shows one embodiment of the predetermined surface relief pattern of the invention, shown in perspective, where relief pattern comprises a regular pattern of linear V-shaped structures. FIG. 10 illustrates another embodiment of the invention, also shown in perspective, where the predetermined surface relief pattern included a plurality of pyramidal structures. Four-sided pyramidal structures are illustrated, however it would be obvious to one skilled in the art that other three dimensional structures are possible, for example a cone or a pyramid having a hexagonal, octagonal or other even-number sided polygon shaped base.

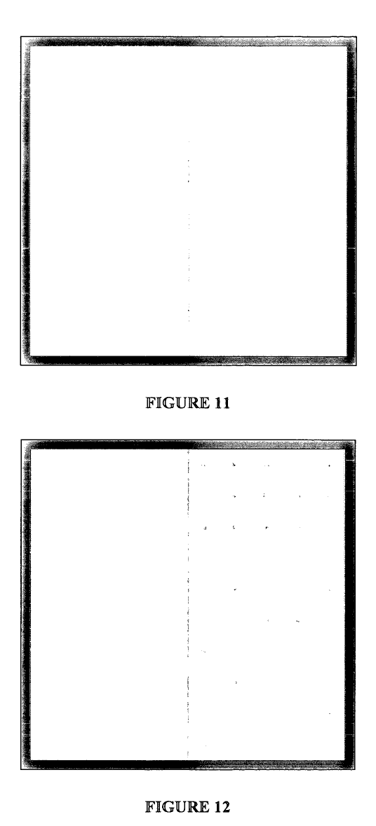

FIG. 11 shows a computer simulation of the level of luminance produced using a conversion system having a surface relief pattern as illustrated in FIG. 9, as seen in a direction normal to the surface relief pattern. This computer simulation used radiative transfer techniques and finite element methods. For comparison, the left-hand side of the image shows the illumination from a prior art planar surface pattern structure. This computer simulation predicts that for θ=30 degrees, wherein θ 75 is indicated in FIG. 8, for example, the increase in luminance and luminous exitance of the patterned surface relative to the planar surface will be approximately 100 percent. The actual increase can be dependent in part on the semispecular reflection properties of the exposed surface material, which cannot be modeled using radiative transfer techniques as this technique assumes diffuse reflections only. Consequently, the optimum angle θ 75 for maximum luminance increase will additionally depend on the optical properties of the conversion material and its binding agent.

FIG. 12 shows a computer simulation of the level of luminance produced using a conversion system having a surface relief pattern as illustrated in FIG. 10, as seen in a direction normal to the surface relief pattern. This computer simulation used radiative transfer techniques and finite element methods. For comparison, the left-hand side of the image shows the illumination from a prior art planar surface pattern structure. The computer simulation predicts that for θ=30 degrees, wherein θ 75 is indicated in FIG. 8, for example, the increase in luminance and luminous exitance of the patterned surface with respect to the planar surface will be approximately 150 percent.

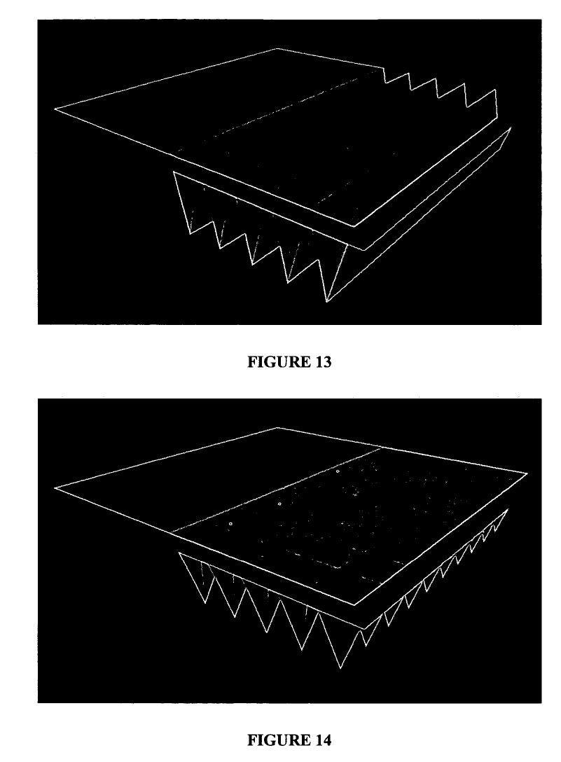

FIG. 13 and FIG. 14 show computer simulations of the level of luminance produced using a conversion system having a surface relief pattern as illustrated in FIGS. 9 and 10, respectively, in perspective view. As shown by the simulations, the luminance of the patterned surfaces does not appear to vary significantly with viewing angle. Therefore the present invention can increase the luminance substantially equally in all viewing directions by increasing its luminous exitance of a variety of light-emitting elements.

The embodiments of the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. An illumination apparatus comprising:
a) one or more light-emitting elements that serve as a primary source of electromagnetic radiation; and
b) a conversion system positioned to interact with the electromagnetic radiation produced by the one or more light-emitting elements, said conversion system having a predetermined surface relief pattern on a face opposite the one or more light-emitting elements, said conversion system further including a conversion means for changing one or more wavelengths of the electromagnetic radiation from the one or more light-emitting elements to electromagnetic radiation having one or more alternate wavelengths;
wherein said one or more light-emitting elements are adapted for connection to a power source for activation thereof.

2. The illumination apparatus according to claim 1, wherein the predetermined surface relief pattern comprises a plurality of “V” shaped grooves or trapezoidal shaped grooves.

3. The illumination apparatus according to claim 2, wherein the grooves are defined by intersecting planes having an angle therebetween varying between 0 and 180 degrees.

4. The illumination apparatus according to claim 3, wherein the angle varies between 20 and 90 degrees.

5. The illumination apparatus according to claim 4 wherein the angle is 30 degrees.

6. The illumination apparatus according to claim 1, wherein the predetermined surface relief pattern comprises a plurality of conical shaped depressions.

7. The illumination apparatus according to claim 1, wherein the predetermined surface relief pattern comprises a plurality of pyramid shaped depressions, the pyramid shaped depressions having polygon bases with an even number of sides.

8. The illumination apparatus according to claim 7, wherein the pyramid shaped depressions are defined by intersecting planes having an angle therebetween varying between 0 and 180 degrees.

9. The illumination apparatus according to claim 8, wherein the angle varies between 20 and 90 degrees.

10. The illumination apparatus according to claim 9 wherein the angle is 30 degrees.

11. The illumination apparatus according to claim 7, wherein the polygon bases are hexagonal, octagonal, square, or rectangular.

12. The illumination apparatus according to claim 7, wherein said pyramid shaped depressions have parabolic curved sides.

13. The illumination apparatus according to claim 1, wherein the predetermined surface relief pattern comprises parabolic grooves.

14. The illumination apparatus according to claim 1, wherein the predetermined surface relief pattern is created by molding, embossing, or stamping.

15. The illumination apparatus according to claim 1, wherein the predetermined surface relief pattern is surface roughened on the face opposite the one or more light-emitting elements.

16. The illumination apparatus according to claim 1, further comprising a brightness enhancement film interposed between said conversion means and said one or more light-emitting elements, said brightness enhancement film providing a means for internally reflecting and refracting said electromagnetic radiation in directions substantially perpendicular to the predetermined surface relief pattern.

17. The illumination apparatus according to claim 16, further comprising an optical element interposed between the one or more light-emitting elements and said brightness enhancement film, said optical element for collecting and collimating the electromagnetic radiation.

18. The illumination apparatus according to claim 1, wherein said one or more light-emitting elements are organic light-emitting diodes.

19. The illumination apparatus according to claim 18, wherein the organic light-emitting diodes have a transparent glass or plastic substrate comprising the predetermined surface relief pattern.

20. The illumination apparatus according to claim 19, wherein the predetermined surface relief pattern is contiguous.

21. The illumination apparatus according to claim 19, wherein the predetermined surface relief pattern is segmented.

22. The illumination apparatus according to claim 1, wherein the one or more light-emitting elements are semiconductor light-emitting diodes and said conversion means comprises one or more layers of inorganic phosphorescent particles formed on the surface relief pattern.

23. The illumination apparatus according to claim 1, wherein said one or more light-emitting elements are quantum dot light-emitting diodes.

24. The illumination apparatus according to claim 23, wherein said conversion means is a quantum dot matrix molded, embossed or stamped with the predetermined surface relief pattern.

25. A method for enhancing luminance produced by one or more point light sources, said method comprising the steps of:
a) providing the one or more point light sources, each comprising a light-emitting element that serves as a primary source of electromagnetic radiation and includes a conversion system for changing one or more wavelengths of the electromagnetic radiation to one or more alternate wavelengths of electromagnetic radiation; and
b) forming a predetermined surface relief pattern on a face of the conversion system, said face being opposite the light-emitting element.

26. The method for enhancing luminance according to claim 25, wherein said step of forming said predetermined surface relief pattern is performed by molding, embossing or stamping.

27. The method for enhancing luminance according to claim 25, wherein said surface relief pattern is selected from the group comprising “V” shaped grooves, trapezoidal shaped grooves, parabolic grooves, conical shaped depressions, pyramid shaped depressions, and pyramid shaped depressions having parabolic curved sides.
